(19) United States
(12) Patent Application Publication
(10) Pub. No.: US 2015/0314588 A1
(43) Pub. Date: Nov. 5, 2015

(54) MESH STRUCTURE AND METHOD FOR MANUFACTURING THE SAME

(71) Applicant: TAIYO CHEMICAL INDUSTRY CO., LTD., Gunma (JP)

(72) Inventors: Chinatsu Chousa, Takasaki-shi, Gunma (JP); Kunihiko Shibusawa, Takasaki-shi, Gunma (JP)

(21) Appl. No.: 14/436,682

(22) PCT Filed: Oct. 18, 2013
(86) PCT No.: PCT/JP2013/078293

§ 371 Date: Apr. 17, 2015

(30) Foreign Application Priority Data
Oct. 26, 2012 (JP) 2012-236438

(51) Int. Cl. B41F 15/34; C23C 18/50; D03D 1/00; C23C 28/00; C23C 14/34; C23C 14/06; C25D 7/06; C23C 16/26; D03D 9/00

(52) U.S. Cl. CPC B41F 15/34; C23C 16/26; C23C 18/50; D03D 1/00; D03D 9/00; C23C 14/34; C23C 14/0605; C25D 7/0607; C23C 28/343

(57) ABSTRACT

One object is to provide a mesh structure wherein junctions in a mesh are reinforced while restricting the degradation of quality due to a plating film. The mesh structure includes an insulating film formed on the top surface of the mesh and a plating film formed on the bottom surface of the mesh so as to fix the intersections of the fiber threads in the mesh. The mesh structure is used for various applications such as a stencil printing plate. The insulating film serves as a masking film for forming the plating film.

### TECHNICAL FIELD

The present invention relates to a mesh structure and a method for manufacturing the mesh structure.

This application is based on and claims the benefit of priority from Japanese Patent Application Serial No. 2012-236438 (filed on Oct. 26, 2012), the contents of which are hereby incorporated by reference in their entirety.

### BACKGROUND

One example of conventional mesh structures is a printing mesh wherein a metal plating film is formed integrally with intersections of fiber threads constituting the mesh so as to prevent displacement of the intersections. In such a printing mesh, sludge or foreign substances may enter the plating film during plating. As a result, the roughness produced in the surface layer of the mesh may degrade the printing quality. Therefore, it has been proposed to grind a screen mesh having a metal plating film to maintain the smoothness of the printing surface and prevent degradation of the printing quality (see, e.g., Japanese Patent Application Publication No. H9-80756).

### SUMMARY

### Problem to be Solved by the Invention

However, such a method involving grinding of a plating film requires extremely high accuracy in the grinding and costly equipment, because the grinding should be performed on, e.g., a metal plating film having a thickness of several micrometers formed on a screen mesh having a fiber diameter of about 10 to 30 μm, and more specifically it should be performed only on a part including sludge or foreign substances. Further, in a plating process on a printing mesh for example, when a plating film is deposited on opening portions in the mesh and block the openings, the printing quality will be seriously degraded. However, it is extremely difficult to grind the plating film on the opening portions in the mesh. There is a demand for a mesh structure wherein junctions (intersections of fiber threads) in the mesh are reinforced while restricting the degradation of quality due to a plating film.

One object of the various embodiments of the present invention is to provide a mesh structure wherein junctions in the mesh are reinforced while restricting the degradation of quality due to a plating film. Other objects of the various embodiments of the present invention will be apparent with reference to the entire description in this specification.

### Means for Solving the Problem

A mesh structure according to an embodiment of the present invention comprises: a mesh formed of fiber threads; an insulating film having an insulation quality formed on at least one surface of the mesh; and a plating film formed on a portion including intersections of the fiber threads in the mesh.

A stencil printing plate according to an embodiment of the present invention comprises the above mesh structure according to an embodiment of the present invention, wherein the one surface of the mesh is arranged as a transfer surface to a printing medium.

A method of fabricating a mesh structure according to an embodiment of the present invention comprises the steps of: preparing a mesh formed of fiber threads (a1); forming an insulating film having an insulation quality on at least one surface of the mesh (b1); and forming a plating film on a portion including intersections of the fiber threads in the mesh (c1).

A method of fabricating a mesh structure according to another embodiment of the present invention comprises the steps of: preparing a mesh formed of fiber threads (a2); forming a plating film on a portion including intersections of the fiber threads in the mesh (b2); forming an insulating film having an insulation quality on at least one surface of the mesh (c2); and removing the plating film on the other surface of the mesh from the mesh structure formed in the step c2 (d2).

### Advantages

The various embodiments of the present invention provide a mesh structure wherein junctions in the mesh are reinforced while restricting the degradation of quality due to a plating film.

### BRIEF DESCRIPTION OF THE DRAWINGS

FIG. 1 is a schematic cross-sectional view illustrating a mesh structure according to an embodiment of the present invention.

FIG. 2 shows a CCD photograph of the top surface of Example 1-1.

FIG. 3 shows a CCD photograph of the bottom surface of Example 1-1.

FIG. 4 shows a CCD photograph of the top surface of Example 1-2 wherein the bottom surface thereof is coated with an electrolytic Ni plating film.

FIG. 5 shows a photograph of a section of Example 1-3.

FIG. 6 shows a CCD photograph of the top surface of a stainless steel plate of Example 7 wherein the Ni plating film is removed.

### DESCRIPTION OF EXAMPLE EMBODIMENTS

Various embodiments of the present disclosure will now be described with reference to the attached drawings. In the drawings, the same or similar components are denoted by the same or similar reference signs, and the detailed description of the same or similar components is appropriately omitted.

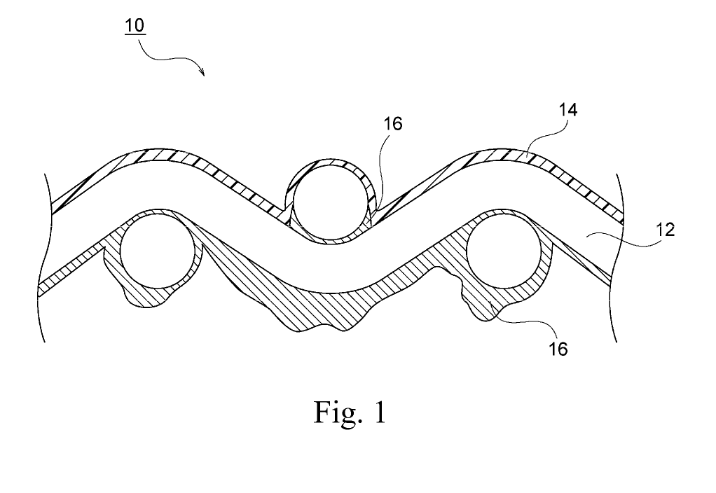

FIG. 1 is a schematic cross-sectional view illustrating a mesh structure 10 according to an embodiment of the present invention. As shown, the mesh structure 10 according to an embodiment may include a mesh 12 formed of woven fiber threads, an insulating film 14 formed on the top surface (on one surface) of the mesh 12, and a plating film 16 formed on the bottom surface (the other surface) of the mesh 12. The mesh structure 10 can be applied to a stencil printing plate, a classifying sieve, a container for cleansing/plating, a filter, etc. FIG. 1 schematically illustrates the mesh structure 10 according to an embodiment of the present disclosure, and it should be noted that dimensional relationship is not accurately reflected in the drawing.

In an embodiment, the mesh 12 may be formed by weaving fiber threads made of a metal such as steel or a metal alloy such as stainless steel. For example, the mesh 12 may have a thread diameter of 15 μm, a thickness of 23 μm, a mesh opening width of 24.7 μm, and a mesh count of 640 (640 meshes per inch). The specifications of the mesh 12 are not limited to those described herein such as the substance, thread diameter, mesh count, uniformity of the size of mesh openings, and positions of mesh openings; these specifications may be varied in accordance with specifics of applications (e.g., printing method, printing pattern, printing medium, and required endurance in the case of a printing screen mesh). For example, the substance of the mesh 12 may be various materials that can form the insulating film 14 and the plating film 16. More specifically, since the insulating film 14 and the plating film 16 in an embodiment can be formed on various resin materials by a known method, the mesh 12 can be formed of various resins such as polypropylene and polyester. Further, the surface layer of the mesh 12 may be previously subjected to a roughening process such as wet plating, sandblasting, honing, or etching, or a smoothening process such as electropolishing or composite electropolishing.

In an embodiment, the insulating film 14 may be a metal oxide film or an amorphous carbon film and may be formed on one surface of the mesh 12 by a known dry process using plasma such as a PVD method and a CVD method. Alternatively, the insulating film 14 may be a polymeric insulating carbon film formed by atmospheric pressure plasma and subatmospheric pressure plasma. It is publicly known that an amorphous carbon film as an example of the insulating film 14 in an embodiment has an electric resistivity (volume resistivity) of about 10⁶ to 10¹¹ Ω·cm; but the electric resistivity and thickness of the insulating film 14 are not particularly limited, because the mesh 12 may have various thread diameters, opening widths, and mesh counts and may be appropriately selected in accordance with various printing applications, and the insulating film 14 may be formed on a part of the mesh 12 where formation of a plating film should be restricted. However, the lower limit of the thickness of the insulating film 14, which may depend on the surface roughness of the mesh 12, should preferably be about 50 nm to 120 nm in consideration of the film continuity of the insulating film 14. The upper limit of the thickness of the insulating film 14 should preferably be about 1 μm to 3 μm. Too large a thickness may cause increase in thread diameter of the mesh 12 and degradation in ductility of the insulating film 14, resulting in lower productivity.

The insulating film 14 can be formed by a progressive plasma dry process, wherein one surface of the mesh 12 may face the plasma source, and the other surface may be fixed on a smooth plate jig having a tabular shape. As compared to the case where the insulating film is formed by, e.g., wet plating or other method using a liquid as a material of the film, the above plasma dry process may have the following features: it may be unnecessary to place the mesh 12 into a bath; no insulating liquid material may adhere to the entirety of the top and bottom surfaces of the mesh 12; and the insulating film is substantially less likely to unnecessarily turn onto the bottom side (the other surface) of the mesh 12 due to the surface tension of the insulating liquid material and the capillary action from the mesh openings occurring during application or spraying of the liquid material of the insulating film 14. Thus, the plasma dry process may simply and effectively restrict the insulating film from turning onto the bottom side of the mesh 12.

In the plasma dry process, it is possible to control the coverage of the insulating film 14 on the mesh fiber threads (the degree of turning onto the bottom side of the mesh 12) by controlling the electric field and the thickness of the film formed, and to restrict production of plasma by using the screened space between the mesh 12 and the plate jig, so as to form the insulating film 14 on a desired surface of the mesh 12. Further, the insulating film 14 formed by the plasma dry process may readily have a thickness as small as about several nano meters to several hundred nano meters, and may be less likely to cause distortion of sizes such as fiber thread diameter of the mesh 12. In the plasma dry process using an electric field, it is publicly known that the insulating film 14 may be first formed on a protrusion in a rough substrate. Therefore, the film forming conditions and the film thickness in the plasma dry process using an electric field may be controlled so as to form the film first around the peaks of the intersections of the fiber threads constituting protrusions in the mesh 12 such that the insulating film 14 is thicker at these portions, thereby further restricting later deposition of the plating film 16 around the peaks of the intersections of the fiber threads.

The insulating film 14 around the openings of the mesh 12 may turn onto a part of the mesh fiber threads corresponding to the sectional part of the openings of the mesh 12 and may turn onto a part of the bottom side of the mesh fiber threads. Thus, the plating film 16 may be restricted from being formed around the openings of the mesh 12. When the insulating film 14 is formed so as to partially turn onto the bottom side of the mesh 12, minute amounts of source gas ingredients and active species may be dispersed on the surface layer of the bottom side of the mesh 12 and detected by elemental analysis; but their amounts are so small that the later deposition of the plating film 16 is substantially not inhibited. That is, in the mesh structure 10 in an embodiment of the present invention, the insulating film 14 may be formed such that the coverage or volume of the insulating film 14 on the surface (the one surface) on which the insulating film 14 is formed may be greater than the coverage or volume of the insulating film 14 on the surface (the other surface) on which the plating film 16 is formed, regardless of whether the insulating film 14 is intentionally or unintentionally formed so as to turn onto the side where the plating film 16 is formed.

The insulating film 14 constituted by an amorphous carbon film can be formed by the plasma CVD method using a hydrocarbon gas such as acetylene as a source gas. The amorphous carbon film may contain at least one element of oxygen, nitrogen, and silicon. The amorphous carbon film containing Si can be formed by the plasma CVD method using a source gas constituted by a hydrocarbon-based gas previously containing Si such as tetramethylsilane, methylsilane, dimethylsilane, trimethylsilane, dimethoxydimethylsilane, and tetramethylcyclotetrasiloxane, and a mixture gas including the gas previously containing Si and a hydrocarbon-based gas such as acetylene. For example, the amorphous carbon film containing O may be formed by a plasma CVD method. For example, a hydrocarbon gas such as acetylene may be made into plasma to form an amorphous carbon film, which may be then subjected to plasma irradiation with an oxygen gas; or, a hydrocarbon-based source gas containing Si or a mixture gas including a source gas containing Si and a hydrocarbon-based source gas may be mixed with oxygen or a carbon dioxide gas containing oxygen at a certain ratio to form the film. The amorphous carbon film containing nitrogen may be formed by a plasma CVD method. For example, a hydrocarbon gas may be made into plasma to form an amorphous carbon film, which may be then subjected to plasma irradiation with a nitrogen gas; or, a hydrocarbon-based source gas such acetylene is mixed with nitrogen at a certain ratio to form the film. The amorphous carbon film in an embodiment may include various elements other than O, N, and Si within the purport of the present disclosure as long as the insulation quality of the amorphous carbon film is not inhibited. Additionally, the amorphous carbon film can be formed by a sputtering method wherein a solid carbon target is placed or other various dry processes. Forming the insulating film 14 of an amorphous carbon film may allow the insulation film 14 to be adhered to the surface layer of the mesh 12 more tightly. This is because the amorphous carbon film has a ductility of about 3 to 5%, which may depend on the thickness of the film.

Further, an amorphous carbon film formed may be irradiated with a source gas containing oxygen and/or nitrogen made into plasma, thereby to increase the wettability between the amorphous carbon film and water. When the mesh structure 10 including a hydrophilic amorphous carbon film is used in a stencil printing plate, the wettability of a water-soluble emulsion, a primary constituent of the stencil printing plate, on the mesh 12 may be increased, blisters are suppressed, and the structural strength of the stencil printing plate may be increased. Further, since the amorphous carbon film contains Si, the amorphous carbon film can be adhered to a printing emulsion more tightly due to reaction of functional groups such as silanol groups formed in the surface layer.

The insulating film 14 in an embodiment can have various unique functions in addition to the function as a film for preventing deposition of the plating film 16 (described later). For example, the insulating film 14 constituted by the amorphous carbon film may well prevent dispersion of UV light; therefore, when the mesh structure 10 in an embodiment is used as a stencil printing plate material, dispersion of UV light can be prevented during pattern drawing using UV light by photolithography on an emulsion applied to the mesh structure 10, resulting in increased accuracy of the patter drawing. Further, when the mesh structure 10 is used as a classification sieve or a rotatory basket for cleaning, the mesh 12 can be provided with a high wear resistance, slidability, or soft metal adhesion preventiveness.

After the insulating film 14 is formed, a thin layer of a fluorine-containing silane coupling agent may be formed on the surface layer of the insulating film 14 to a thickness of about 20 nm, before the plating film 16 is formed. Thus, a water-repellent coating having an insulation quality may be provided to such a thickness as not to impact the later deposition of the plating film 16 on relevant locations. Such a coating may further suppress the deposition of the plating film 16 on the surface layer of the insulating film 14 during forming of the plating film 16.

The insulating film 14 may contain silicone oxide, titanium oxide, aluminum oxide, or zirconia oxide, which may securely fix the coupling agents such as fluorine-containing silane coupling agents. Surface modification (improvement of water repellence or water and oil repellence) of the mesh 12 can be achieved by forming a thin coating film of a coupling agent on at least a part of the insulating film 14.

In an embodiment, the plating film 16 may be constituted by various known electroless plating films or electrolytic plating films in accordance with its application or use. The plating film 16 may be a plating film of an alloy. Suitable examples of such an alloy may include Ni—Co alloy and Ni—W alloy. Further, the plating film 16 may be a laminated plating film formed of a plurality of plating layers. In an embodiment, the plating film 16 may be formed by the electrolytic Ni plating or electrolytic Cr plating so as to fix the portions where fiber threads of the mesh 12 cross each other (intersections). Thus, the fiber threads may be prevented from being displaced at the intersection. Thus, since the mesh fiber threads are fixed with the metal plating film, the junctions in the mesh 12 may be provided with a metal rigidity and ductility in accordance with the appropriately selected and deposited plating film material, as compared to bonding using a metal oxide film, bonding using an amorphous carbon film or a ceramic film such as glass, and diffusion bonding wherein the metal fiber thread intersections may be heated at about 700° C. and simultaneously pressurized so as to diffuse and integrate the metal between the mesh fiber threads. The bonding of intersections by wet plating may be achieved at a relatively low temperature and normal pressures, as the electrolytic Ni plating bath has a temperature of about 50 to 60° C.; therefore, heating of the mesh fiber threads at a high temperature may not modify the physical properties such as ductility of the mesh fiber threads, and oxidation of the mesh fiber threads may not modify the surface wettability of the mesh fiber threads. Further, when the bonding is achieved with an adhesive, the adhesive may be spread onto an opening portion of the mesh by surface tension to form a film across an entire opening of the mesh. In contrast, a metal plating film may wrap up an intersection of the mesh fiber threads having a complex shape. Further, wet plating may require low cost and achieve a high film forming rate, resulting in extremely high productivity.

As described above, the plating film 16 can also be formed on a resin mesh by a known method. For example, when the mesh 12 is formed of a resin material such as polypropylene or polyester, the surface layer of the mesh 12 serving as a substrate may be subjected to a pre-plating treatment such as honing, Pd treatment, or sandblasting, before an electroless Ni plating film may be formed as the plating film 16, which can be achieved by a known method.

In an embodiment, the insulating film 14 may serve as a masking film for forming the plating film 16. More specifically, in the mesh structure 10 in an embodiment, the insulating film 14 may be first formed on one surface of the mesh 12, and then the mesh 12 having the insulating film 14 formed thereon may be placed into a plating bath to form the plating film 16. During the plating, the insulating film 14 may be formed of an insulating metal oxide or an amorphous carbon film. The plating metals are less likely to deposit on these materials, and these materials may be less tightly adhered to the plating metals; therefore, the plating film 16 is less likely to be formed on the insulating film 14 and may be formed on the other surface to fix the intersections of the fiber threads in the mesh 12. Even if the plating metal deposits on the insulating film 14 due to deficiency of pinholes or insulating quality, the plating film can be readily removed by ultrasonic cleansing, peeling with an adhesive tape, friction with a dry cloth, or other appropriate methods, as compared to the plating film depositing on a metal film. As described above, when a plating film is applied to bonding of the intersections of mesh fiber threads, the plating film may grow less anisotropically and substantially evenly around the fiber threads of the mesh to enlarge the thread diameter. In addition, since such a plating film is formed in a bath, it may be difficult to control the location of deposition, and the plating film formed may include sludge produced in the bath. However, the insulating film 14 of the mesh 12 according to an embodiment of the present invention may be formed on the surface on which no plating film 16 is formed; therefore, the initial size of the mesh fiber threads and the smoothness of the mesh 12 can be maintained. Further, around the openings in the mesh 12, the insulating film 14 may be formed so as to turn onto the side where the plating film 16 is formed (e.g., the mesh fiber thread portion constituting a section of a through hole of an opening in the mesh 12). Thus, the plating film 16 may be prevented from being formed around the opening and blocking the opening. In the mesh structure 10 in an embodiment of the present invention, the plating film 16 may be formed such that the coverage or volume of the plating film 16 on the surface (the other surface) on which the plating film 16 is formed may be greater than the coverage or volume of the insulating film 16 on the surface (the one surface) on which the insulating film 14 is formed.

In thus formed mesh structure 10 according to an embodiment, the intersections of the fiber threads in the mesh 12 may be fixed with the plating film 16; therefore, the intersections of the mesh fiber threads may be prevented from being displaced. In addition, the insulating film 14 of the mesh structure 10 may have a smaller thickness as compared to the plating film 16 and may include less sludge than in plating processes. Accordingly, when the mesh structure 10 according to an embodiment is used as a stencil printing plate for example, the side where the insulating film 16 may be formed may be positioned so as to face a transfer surface to a printing medium (on a printing substrate side or a printing transfer sheet side), thereby to restrict degradation in printing quality. This is advantageous particularly in thin film printing. Further, since the intersections of the fiber threads in the mesh 12 is fixed with the plating film 16, degradation in position accuracy (size deformation) of the pattern of the stencil printing plate due to repeated printing by squeezing can also be restricted.

Further, in the mesh structure 10 according to an embodiment, the insulating film 14 and the plating film 16 may not necessarily formed on the entire surface of the mesh 12 but may be formed on a part of the mesh 12. For example, when the mesh structure 10 in an embodiment is used as a stencil printing plate, the portion that impact the printing quality may mainly include the portion of the stencil printing plate where an emulsion is applied and the printing pattern portion. When the mesh structure 10 in an embodiment is used as a sieve, the portion that impacts the function of the sieve may be the portion other than the portion pasted on the frame. The insulating film 14 and the plating film 16 may not necessarily be formed on the portion which is necessary in setting a mesh with a tension and then is removed and the portion to be adhered onto other portions.

In the mesh structure 10 according to an embodiment, the insulating film 14 may be removed. The insulating film 14 may be removed by, e.g., plasma sputtering, plasma ashing, decomposition through heat oxidation, or alkaline etching. For example, when the insulating film 14 is constituted by an amorphous carbon film formed of carbon or of hydrogen and carbon, the insulating film 14 can be readily removed by a known oxygen plasma ashing method with a CVD apparatus using an oxygen gas as a main material, and then a reduction process can be performed as necessary by a known method. When the insulating film 14 is constituted by a metal oxide film, the insulating film 14 can be removed through etching by a known RF plasma sputtering method using an inactive gas such as an Ar gas as a sputtering gas. Thus, the mesh structure 10 can be made thinner. When the insulating film 14 is formed as an amorphous carbon film composed mainly of hydrogen and carbon, the insulating film 14 can be readily removed by ashing wherein the film may be heated in the air (atmosphere) to about 350° C.

Next, a mesh structure 20 according to another embodiment of the present invention will be described. The mesh structure 20 according to the other embodiment may include a mesh 12, an insulating film 14, and a plating film 16 that may be formed of the same substance in the same manner as in the mesh structure 10 in the above-described embodiment. In the mesh structure 20 in the other embodiment, a Ni plating film 16 composed mainly of sulfamic acid Ni plating bath may be previously formed on the mesh 12 so as to fix the intersections of the fiber threads of the mesh 12, then an insulating film 14 formed of an amorphous carbon film having a high acid resistance may be formed on one surface of the mesh 12, and the mesh 12 having the insulating film 14 formed thereon may be immersed into an etching liquid including nitric acid and hydrogen peroxide. Such a known method may be used to melt and remove the Ni plating film 16 on the portion not covered by the insulating film 14. Alternatively, when the plating film 16 is formed as an electrolytic Sn plating film and then an insulating film formed of an amorphous carbon film having a high acid resistance is formed on one surface of the mesh 12, the insulating film 14 can be melted and removed more readily by immersing the Sn plating film into an acid etching liquid. When the plating film 16 is formed of a Ni plating film, the fiber thread portion of the mesh 12 from which the plating film 16 has been melted and removed can be restored to its original pretreatment substrate shape, and the dust in the plating film 16 can be removed together.

Thus, in the mesh structure 20 in the other embodiment, the intersections of the fiber threads of the mesh 12 may be fixed with the plating film 16, then an insulating film 14 may be formed on one surface to cover the intersections of the fiber threads, and the plating film 16 may be removed. If the plating film is formed on the entire surface of the mesh fiber threads, the diameter of the mesh fiber threads is made larger. This may cause increase in thickness of an emulsion layer and blocking of mesh openings on the transfer surface (on a printing substrate side or a printing transfer sheet side) to a printing medium in a stencil printing plate using an emulsion, resulting in variation of the volume of a printing ink transmitted. The mesh structure 20 according to the other embodiment may be free of such a problem since the plating film 16 may be removed.

### EXAMPLES

It was confirmed by the following method that a mesh structure according to one embodiment of the present invention has no plating film formed on the surface on which the insulating film 14 (amorphous carbon film) is formed.

First, eight pieces of 500 mesh (500-19) made of stainless steel (SUS304) were prepared. The size of the prepared meshes was 10 cm by 10 cm.

A mesh was placed flat on a flat sample substrate made of stainless steel, and an amorphous carbon film containing Si and oxygen was formed to a thickness of about 50 nm on one surface of the mesh irradiated with plasma by a known plasma CVD method (Example 1-1). More specifically, after a known plasma pretreatment, an amorphous carbon film containing Si was formed by a plasma CVD method using a trimethylsilane gas as a source gas. Then, the substrate was irradiated with oxygen plasma by a plasma CVD method using oxygen as a source gas. An untreated mesh was taken as Comparative Example 1-1.

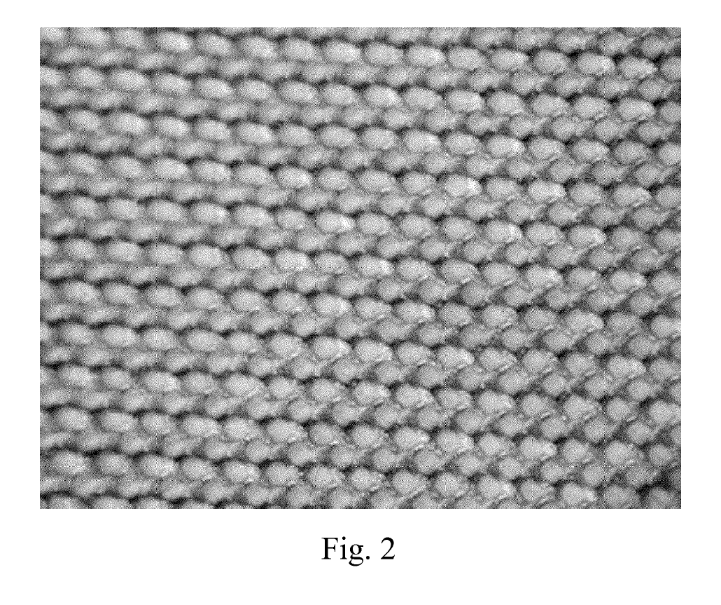

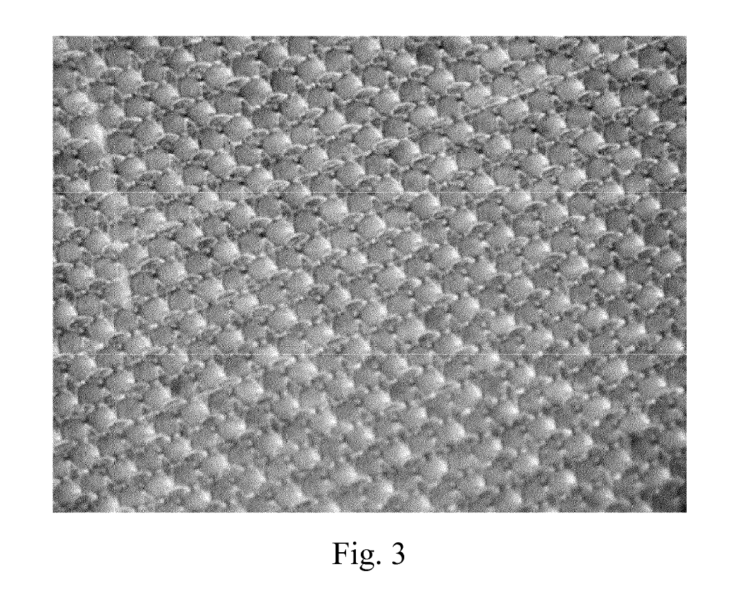

Observation was made on Example 1-1 via the CCD photographs of the surface on which an amorphous carbon film containing Si and oxygen was formed (top surface) and the surface facing the sample substrate (bottom surface). FIG. 2 shows a CCD photograph of the top surface of Example 1-1. As shown, an interference color pattern can be observed over the entirety of the amorphous carbon film, indicating that the amorphous carbon film is formed on the top surface. FIG. 3 shows a CCD photograph of the bottom surface of Example 1-1. The photograph shows the color of the bare stainless steel over the entire surface and no interference color of the amorphous carbon film, indicating that the amorphous carbon film did not turn onto the bottom surface.

Next, the meshes of Example 1-1 and Comparative Example 1-1 were suspended in a plating bath mainly containing sulfamic acid Ni, and an electrolytic Ni plating film was formed to a thickness of about 3 μm on the meshes made of stainless steel by a known method with a plating current density of 1 A/dm². Example 1-1 having a Ni plating film formed thereon was taken as Example 1-2, and Comparative Example 1-1 having a Ni plating film formed thereon was taken as Comparative Example 1-2. The mesh of Example 1-1 was placed into the plating bath such that the surface on which no amorphous carbon film is formed faces the anode of the Ni plating bath. No masking with a backing-plate for example was done on the bottom surface.

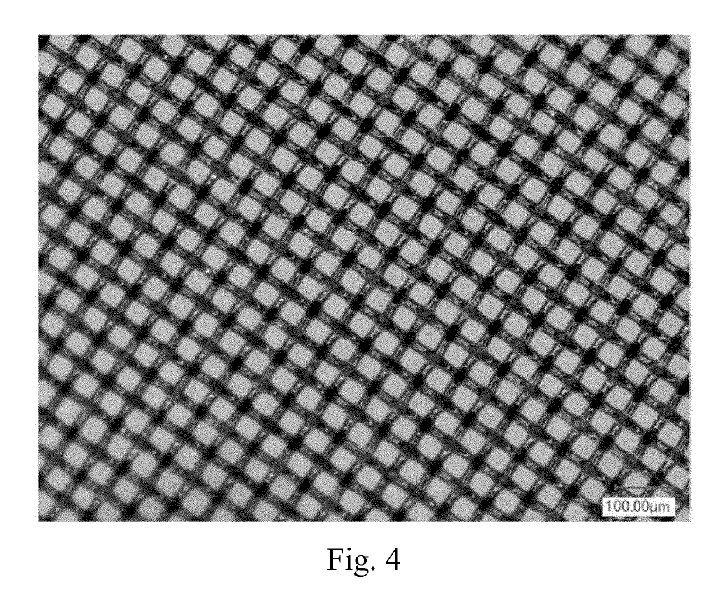

Observation of an electrolytic Ni plating film was made on Example 1-2 via the CCD photographs of the surface on which an amorphous carbon film containing Si and oxygen was formed. The CCD photograph is shown in FIG. 4. It can be observed that no Ni plating having a metallic luster is formed, even on the peaks of the intersections where mesh threads cross each other (the portions crushed by calender process) and the surface of the fiber threads of the mesh. Further, observation of an electrolytic Ni plating film was made on Example 1-2 via the CCD photographs of the surface on which no amorphous carbon film was previously formed. As a result, It was observed that a Ni plating having a metallic luster is formed, even on the peaks of the intersections where mesh threads cross each other (the portions crushed by calender process) and the surface of the fiber threads of the mesh. Also, it was observed that the Ni plating having a metallic luster was formed so as to bond the junctions of the mesh fiber threads crossing each other. As for Comparative Example 1-2, it was observed that the Ni plating film was formed on both surfaces.

As described above, if the Ni plating is formed so as to bond the junctions of the mesh fiber threads crossing each other, the intersections in the mesh are fixed and reinforced by the tight adhesion of the Ni plating on the substrate (the fiber threads of the mesh made of stainless steel) and the rigidity of the Ni plating that straddle (fasten) the intersections. The degree at which the Ni plating fixes and reinforces the intersections in the mesh was determined in an experiment. First, the same sample mesh made of stainless steel as Example 1-2 was placed flat on a flat sample substrate made of stainless steel, and then an amorphous carbon film containing Si was formed to a thickness of about 140 nm on only one surface of the sample mesh by a known plasma CVD method using a trimethylsilane gas as a source gas. Then, the trimethylsilane gas was exhausted, and the substrate was irradiated with oxygen plasma. Further, the sample mesh was placed flat on the flat sample substrate made of stainless steel such that the surface of the sample mesh made of stainless steel on which no amorphous carbon film is formed faces upward (toward the plasma source). Then, the sample mesh was irradiated with plasma of a mixture gas of Ar and hydrogen by a known plasma CVD method, while the substrate is subjected to an applied voltage of −3.5 kVp. The surface on which no amorphous carbon film is formed is subjected to etching and reduction processes (cleaning of passive layer portion of the surface layer of stainless steel) by a known method. Next, the sample mesh was placed into the Ni plating bath such that the surface on which no amorphous carbon film is formed faces the anode and was subjected to Ni plating at 0.5 A/dm² for 15 minutes. This sample mesh was taken as Example 1-3.

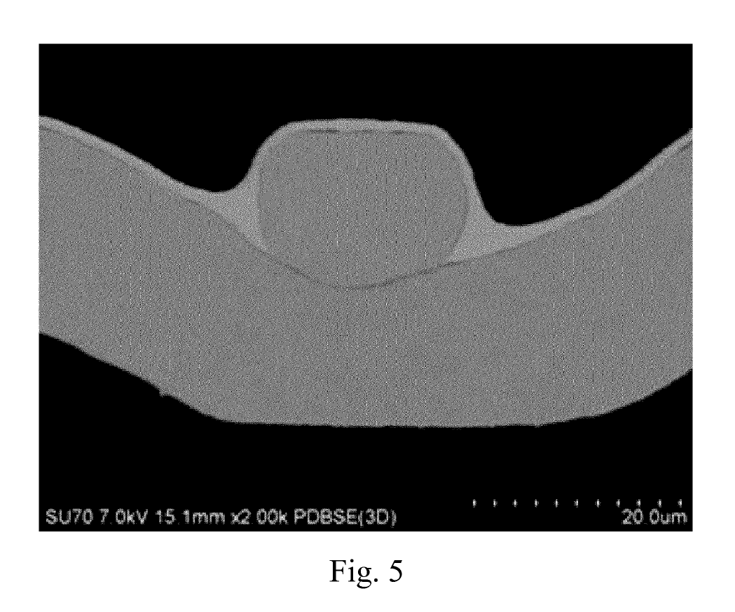

Next, a part of the mesh fiber threads of Example 1-3 was cut off, and the sectional surfaces of the intersections of the mesh fiber threads were polished and then observed under an electron microscope. The photograph of the sectional surface is shown in FIG. 5. In the top side of the photograph, the Ni plating layer is deposited on the surface layer of the fiber threads of the mesh made of stainless steel; the Ni plating layer can be observed to have a different color than the stainless steel fiber threads serving as a substrate. It can also be observed in the top side of the photograph that the Ni plating turns and enters into the gaps on the intersections where the fiber threads of the mesh cross each other. Further, in the bottom side of the photograph, no Ni plating film is formed on the fiber thread of the mesh; the mesh fiber threads have increased the thickness thereof toward the bottom of the photograph only by the thickness of the amorphous carbon film containing Si and oxygen being about 140 nm. That is, it was confirmed that, because of absence of the Ni plating layer having a thickness of about 3,000 nm, the initial size of the fiber threads of the mesh is maintained, and the enlargement of the fiber threads due to the Ni plating layer formed is prevented.

Next, a stainless steel mesh of Example 1-3 (having an amorphous carbon film formed on one surface and Ni plating deposited on the other surface) was prepared to a width of 10 mm, a length of 100 mm, and a mesh bias of 0°, and an untreated stainless steel mesh having the same shape was taken as Comparative Example 2. The tensile strengths of these meshes were compared in view of a stress-strain graph. Each of the samples of Example 1-3 and Comparative Example 2 was clamped at two opposing short sides thereof and set in a universal tester Instron 5865 to determine the amount of strain (elongation percentage) of the sample being stretched under a certain amount of strain in a longitudinal monoaxial direction of the sample. The elongation percentage of Example 1-3 stretched under a stress of 30 N was approximately 0.5%, while the elongation percentage of Comparative Example 2 stretched under a stress of 30 N was approximately 0.9%. Comparative Example 2 had about twice as large a stress (elongation percentage) as Example 1-3 (a large stress). Further, the elongation percentage of Example 1-3 stretched under a stress of 40 N was approximately 0.7%, while the elongation percentage of Comparative Example 2 stretched under a stress of 40 N was approximately 1.5%. Comparative Example 2 had about twice as large a stress as Example 1-3. Further, the elongation percentage of Example 1-3 stretched under a stress of 50 N was approximately 1%, while the elongation percentage of Comparative Example 2 stretched under a stress of 50 N was approximately 2.5%. Comparative Example 2 had about 2.5 times as large a stress as Example 1-3. Thus, it was confirmed that Example 1-3 largely suppresses the amount of strain with respect to a tensile stress as compared to Comparative Example 2. This is because the intersections of the fiber threads in the mesh of Example 1-3 are fixed by Ni plating at one side thereof.

The remaining four meshes were processed as follows. An amorphous carbon film containing Si and oxygen as in Example 1-1 was formed on one surface, and then a fluorine-containing silane coupling agent (Fluorosurf FG-5010Z130-0.2 from Fluoro Technology Corporation) was applied to the surface of the amorphous carbon film to provide water and oil repellence (Example 2). An amorphous carbon film containing Si was formed as a ground adhesion layer to a thickness of about 20 nm using a trimethylsilane gas as a source gas, and then another amorphous carbon film containing hydrogen and carbon was formed on one surface to a thickness of about 50 nm using acetylene as a source gas (Example 3). An amorphous carbon film containing Si was formed on one surface using a trimethylsilane gas as a source gas (Example 4). The amorphous carbon films of Examples 2 and 4 were formed to a thickness of about 50 nm by a known plasma CVD method, and then electrolytic Ni plating films were formed by a known method as in Example 1-2. As a result, no electrolytic Ni plating film was observed on the surfaces of the amorphous carbon films. Likewise, no electrolytic Ni plating film was observed on a mesh like Example 1-2 having an amorphous carbon film with a thickness of about 120 nm (Example 5, having a higher coverage of the amorphous carbon film on the surface of the fiber threads of the mesh).

As to Deposition of Ni Plating Film on a Metal Oxide Film and Adhesion Therebetween

Next, three rectangular plates made of stainless steel (SUS304) having a width of 40 mm, a length of 100 mm, and a thickness of 0.5 mm were prepared. On one of the three plates was formed a titanium oxide film to a thickness of about 35 nm by a known plasma sputtering method. This plate was taken as Example 6. On another one of the three plates was formed an Al₂O₃ film to a thickness of about 35 nm by a known plasma sputtering method. This plate was taken as Example 7. The remaining stainless steel plate was left untreated and taken as Comparative Example 3. More specifically, the stainless steel (SUS304) substrate and a TiO₂ or Al₂O₃ target were placed on the turntable in the reaction container of the SRDS-7000 general-purpose compact deposition apparatus (from Sanyu Electron Co., Ltd.) so as to be mutually opposed, and the reaction container was evacuated to 1×10⁻⁴ Pa. After the substrate was subjected to reverse sputtering, sputtering was performed using a sputtering gas constituted by a mixture gas of Ar gas and O₂ gas each having a flow rate of 100 sccm, under the conditions of a gas pressure of the mixture gas of 10 Pa, an RF output of 400 W, a target-substrate (T-S) distance of 100 mm, an offset of 55 mm, and a sample table rotation rate of 10 rpm, thereby to form a TiO₂ film layer (Example 6) or an Al₂O₃ film layer (Example 7) on the substrate.

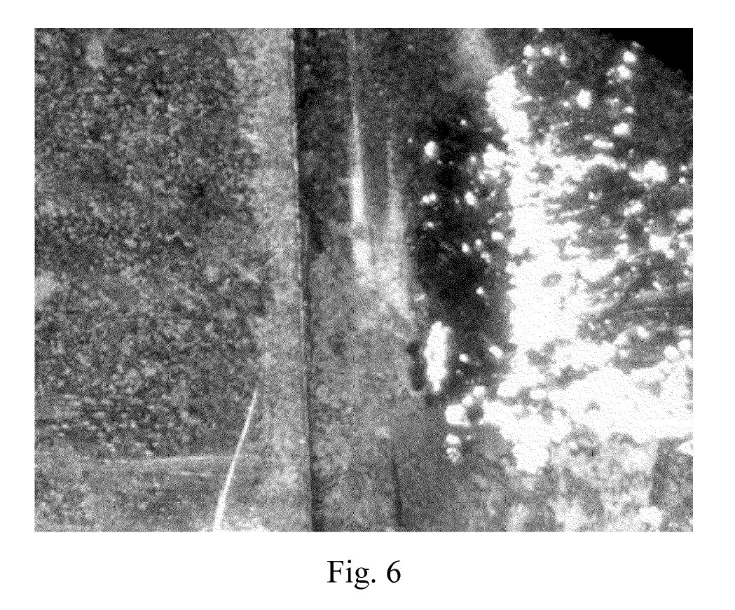

Next, the stainless steel plates of Examples 6 and 7 and Comparative Example 3 were suspended in a sulfamic acid Ni bath, and plating was performed such that an electrolytic Ni plating film was formed on ordinary stainless steel to a thickness of about 3 μm by a known method of forming a plating film with a current density of 1 A/dm². Since the metal oxide films formed in Examples 6 and 7 have small thicknesses, the Ni plating film was formed on the metal oxide films formed in Examples 6 and 7, in addition to Comparative Example 3. Then, a commercially available adhesive tape (cellophane tape T-SK18N from KOKUYO Co., Ltd.) was pasted on and removed from the surfaces of the stainless steel plates of Examples 6 and 7 and Comparative Example 3 on which the Ni plating film was formed. As a result, it was observed that the plating films of Examples 6 and 7 were readily peeled, while the Ni plating film of Comparative Example 3 was not peeled. FIG. 6 shows the CCD photograph of Example 7 having the Ni plating film peeled. The photograph shows the Ni plating film (the portion having metallic luster) pasted on the adhesive tape and peeled from the substrate in a part of the adhesive tape in the right side of the photograph (a part of the portion extending from the border between the substrate (in the left side) extending vertically in a form of a line at a position somewhat offset leftward from the center of the photograph and the adhesive tape (in the right side) to the right end). Thus, the Ni plating film deposited on the insulating layer can be readily peeled or removed even in the case where the insulating layer is formed to a thickness not large enough to suppress deposition of plating (to a thickness and with an insulation resistance not sufficient to suppress deposition of plating).

### LIST OF REFERENCE NUMBERS

10, 20 mesh structures
12 mesh
14 insulating film
16 plating film

What is claimed is:

1. A mesh structure comprising:
a mesh formed of fiber threads;
an insulating film having an insulation quality formed on at least one surface of the mesh; and
a plating film formed on a portion including intersections of the fiber threads in the mesh.

2. The mesh structure of claim 1 wherein the insulating film is formed on both surfaces of the mesh such that a coverage or volume of the insulating film on the one surface is greater than the coverage or volume of the insulating film on the other surface of the mesh.

3. The mesh structure of claim 1 wherein the plating film is formed on at least the other surface of the mesh.

4. The mesh structure of claim 3 wherein the plating film is formed on both surfaces of the mesh such that a coverage or volume of the plating film on the one surface is smaller than the coverage or volume of the plating film on the other surface.

5. The mesh structure of claim 1 wherein the plating film is formed by plating the mesh having the insulating film formed thereon.

6. The mesh structure of claim 1 wherein the insulating film is removed.

7. The mesh structure of claim 1 wherein the insulating film is formed on the plating film.

8. The mesh structure of claim 1 wherein the insulating film is constituted by a metal oxide film or an amorphous carbon film.

9. The mesh structure of claim 1 wherein the insulating film is formed by a dry process.

10. A stencil printing plate comprising the mesh structure of claim 1, wherein the one surface of the mesh is arranged as a transfer surface to a printing medium.

11. A method of fabricating a mesh structure, comprising the steps of:
preparing a mesh formed of fiber threads (a1);
forming an insulating film having an insulation quality on at least one surface of the mesh (b1); and
forming a plating film on a portion including intersections of the fiber threads in the mesh (c1).

12. The method of fabricating a mesh structure of claim 11 further comprising the step of removing the insulating film from the mesh structure formed in the step c1 (d1).

13. A method of fabricating a mesh structure, comprising the steps of:
preparing a mesh formed of fiber threads (a2);
forming a plating film on a portion including intersections of the fiber threads in the mesh (b2);
forming an insulating film having an insulation quality on at least one surface of the mesh (c2); and
removing the plating film on the other surface of the mesh from the mesh structure formed in the step c2 (d2).
